(19) United States
(12) Patent Application Publication
(10) Pub. No.: US 2013/0328167 A1
(43) Pub. Date: Dec. 12, 2013

(54) SELF-ALIGNED METAL-INSULATOR-METAL (MIM) CAPACITOR

(71) Applicants: Chih-Chao Yang, Glenmont, NY (US); Daniel C. Edelstein, White Plains, NY (US); Baozhen Li, South Burlington, VT (US); Keith Kwong Hon Wong, Wappingers Falls, NY (US)

(72) Inventors: Chih-Chao Yang, Glenmont, NY (US); Daniel C. Edelstein, White Plains, NY (US); Baozhen Li, South Burlington, VT (US); Keith Kwong Hon Wong, Wappingers Falls, NY (US)

(73) Assignee: INTERNATIONAL BUSINESS MACHINES CORPORATION, Armonk, NY (US)

(21) Appl. No.: 13/489,940

(22) Filed: Jun. 6, 2012

(51) Int. Cl. H01L 29/92; H01L 21/02

(52) U.S. Cl. 257/532; 438/396; 257/E29.343; 257/E21.008

(57) ABSTRACT

A metal-insulator-metal (MIM) capacitor structure integrated within a back-end-of-the-line (BEOL) structure is provided. The MIM capacitor structure includes a lower electrode, i.e., a first conductive material, embedded within a dielectric material of the BEOL structure, a dielectric material liner having a dielectric constant of equal to, or greater than, silicon dioxide located atop the lower electrode, and an upper electrode, i.e., a second conductive material, positioned between vertical portions of the dielectric material liner and atop a horizontal connecting portion of the dielectric material liner. In accordance with the present disclosure, the vertical portions of the dielectric material liner do not extend onto an upper surface of the dielectric material that includes the lower electrode.

### BACKGROUND

The present disclosure relates to a semiconductor structure and more particularly to a metal-insulator-metal (MIM) capacitor structure and a method for forming the MIM capacitor structure.

As semiconductor devices continue to shrink, there is a desire to decrease the area occupied by features, such as capacitors. To accommodate, capacitors are being formed over transistors (e.g., in the metal interconnect level) as opposed to being formed at the device (e.g., transistor) level nearer the semiconductor substrate. One example of such a capacitor is a metal-insulator-metal (MIM) capacitor.

The integration of MIM capacitors into a back-end-of-line (BEOL) structure typically requires three extra masks (i.e., an alignment mask, a top electrode mask and a bottom electrode mask) and etching steps to form the capacitors, which may increase overall fabrication costs. Also, the integration of MIM capacitors into BEOL structures oftentimes over-etches the top plate electrode causing dielectric damage around at least one edge of the MIM capacitor. This over-etching can cause reliability concerns, such as, for example, early time-dependent-dielectric breakdown (TDDB) failure. Moreover, the capacitor-dielectric thickness is typically required to be thicker than 500 Å in order to ensure sufficient process window during top-electrode etch. This requirement limits the extendibility of the process to next technology generations. Furthermore, the high resistivity electrode material, TiN, limits the Q factor of prior art MIM capacitors. Consequently, products containing MIM capacitors formed by conventional methods are economically uncompetitive in view of their high costs and poor performance.

### SUMMARY

The present disclosure provides a MIM capacitor structure that is integrated within a BEOL structure which overcomes the numerous drawbacks associated with prior art MIM capacitor structures. The MIM capacitor structure of the present disclosure includes a lower electrode, i.e., a first conductive material, embedded within a dielectric material of the BEOL structure, a dielectric material liner having a dielectric constant of equal to, or greater than, silicon dioxide (e.g., silicon dioxide has a dielectric constant of 4.0) located atop the lower electrode, and an upper electrode, i.e., a second conductive material, positioned between vertical portions of the dielectric material liner and atop a horizontal connecting portion of the dielectric material liner. In accordance with the present disclosure, the vertical portions of the dielectric material liner do not extend onto an upper surface of the dielectric material that includes the lower electrode. As such, a self-aligned MIM capacitor structure is provided in the present disclosure.

In one aspect of the present disclosure, a semiconductor structure, i.e., MIM capacitor structure, is provided. The MIM capacitor structure includes a diffusion barrier and a first conductive material embedded within a dielectric material. The diffusion barrier separates the first conductive material from the dielectric material. The diffusion barrier and the first conductive material have upper surfaces that are coplanar with an upper surface of the dielectric material. The structure further includes insulator material portions that are present at least on the upper surface of the dielectric material. Each insulator material portion has a sidewall surface that is vertically coincident to an outermost vertical edge of the diffusion barrier or an outermost vertical edge of the first conductive material. The structure of the present disclosure further includes a dielectric material liner having a dielectric constant of equal to, or greater than, silicon dioxide located atop the first conductive material and between the insulator material portions. The dielectric material liner has vertical portions that extend from a horizontal connecting portion. The structure further includes a second conductive material positioned between the vertical portions of the dielectric material liner and located atop the horizontal connecting portion of the dielectric material liner. The dielectric material liner and the second conductive material have upper surfaces that are coplanar with each other and with an upper surface of each insulator material portion.

In another aspect, a method of forming a semiconductor structure, i.e., MIM capacitor structure, is provided. The method includes forming a diffusion barrier and a first conductive material embedded within a dielectric material. In accordance with the present disclosure, the diffusion barrier separates the first conductive material from the dielectric material. Also, the diffusion barrier and the first conductive material have upper surfaces that are coplanar with an upper surface of the dielectric material. Next, insulator material portions are provided on at least the upper surface of the dielectric material. Each insulator material portion has a sidewall surface that is vertically coincident to an outermost vertical edge of the diffusion barrier or an outermost vertical edge of the first conductive material. A dielectric material liner having a dielectric constant of equal to, or greater than, silicon dioxide (e.g., 4.0) and a second conductive material are then formed between the insulator material portions. The dielectric material liner is positioned between the first and second conductive materials, and the dielectric material liner and the second conductive material have upper surfaces that are coplanar with each other and with an upper surface of each insulator material portion.

### BRIEF DESCRIPTION OF THE DRAWINGS

FIG. 1 is a pictorial representation (through a cross sectional view) illustrating a dielectric material that can be employed in one embodiment of the present disclosure.

FIG. 2 is a pictorial representation (through a cross sectional view) illustrating the structure of FIG. 1 after forming at least one opening in the dielectric material.

FIG. 3 is a pictorial representation (through a cross sectional view) illustrating the structure of FIG. 2 after forming a diffusion barrier and a first conductive material within the at least one opening.

FIG. 4A is a pictorial representation (through a cross sectional view) illustrating the structure of FIG. 3 after selective deposition of a sacrificial metal material on the upper surface of the first conductive material in accordance with one embodiment of the present disclosure.

FIG. 4B is a pictorial representation (through a cross sectional view) illustrating the structure of FIG. 3 after selective deposition of a sacrificial metal material on the upper surface of both the first conductive material and the diffusion barrier in accordance with another embodiment of the present disclosure.

FIG. 5A is a pictorial representation (through a cross sectional view) illustrating the structure of FIG. 4A after deposition of an insulator material and then etching back the insulator material.

FIG. 5B is a pictorial representation (through a cross sectional view) illustrating the structure of FIG. 4B after deposition of an insulator material and then etching back the insulator material.

FIG. 6A is a pictorial representation (through a cross sectional view) illustrating the structure of FIG. 5A after selectively removing the sacrificial metal material exposing the upper surface of the first conductive material.

FIG. 6B is a pictorial representation (through a cross sectional view) illustrating the structure of FIG. 5B after selectively removing the sacrificial metal material exposing the upper surface of both the first conductive material and the diffusion barrier.

FIG. 7A is a pictorial representation (through a cross sectional view) illustrating the structure of FIG. 6A after deposition of an optional adhesion layer.

FIG. 7B is a pictorial representation (through a cross sectional view) illustrating the structure of FIG. 6B after deposition of an optional adhesion layer.

FIG. 8A is a pictorial representation (through a cross sectional view) illustrating the structure of FIG. 7A after deposition of a dielectric material having a dielectric constant that is equal to, or greater than, silicon dioxide.

FIG. 8B is a pictorial representation (through a cross sectional view) illustrating the structure of FIG. 7B after deposition of a dielectric material having a dielectric constant that is equal to, or greater than, silicon dioxide.

FIG. 9A is a pictorial representation (through a cross sectional view) illustrating the structure of FIG. 8A after deposition of a second conductive material and etching back the second conductive material.

FIG. 9B is a pictorial representation (through a cross sectional view) illustrating the structure of FIG. 8B after deposition of a second conductive material and etching back the second conductive material.

FIG. 10A is a pictorial representation (through a cross sectional view) illustrating the structure of FIG. 9A after deposition of another dielectric material.

FIG. 10B is a pictorial representation (through a cross sectional view) illustrating the structure of FIG. 9B after deposition of another dielectric material.

FIG. 11A is a pictorial representation (through a cross sectional view) illustrating the structure of FIG. 10A after formation of a contact via and filling the contact via with a third conductive material.

FIG. 11B is a pictorial representation (through a cross sectional view) illustrating the structure of FIG. 10B after formation of a contact via and filling the contact via with a third conductive material.

### DETAILED DESCRIPTION

The present disclosure, which provides a metal-insulator-metal (MIM) capacitor structure and a method of forming the same, will now be described in greater detail by referring to the following discussion and drawings that accompany the present application. Throughout the drawings, the same reference numerals or letters are used to designate like or equivalent elements. The drawings are not necessarily drawn to scale. For purposes of the description hereinafter, the terms “upper”, “lower”, “right”, “left”, “vertical”, “horizontal”, “top”, “bottom”, and derivatives thereof shall relate to the components, layers and/or elements as oriented in the drawing figures which accompany the present application.

In the following description, numerous specific details are set forth, such as particular structures, components, materials, dimensions, processing steps and techniques, in order to provide a thorough understanding of the present disclosure. However, it will be appreciated by one of ordinary skill in the art that the present disclosure may be practiced without these specific details. In other instances, well-known structures or processing steps have not been described in detail in order to avoid obscuring the present disclosure.

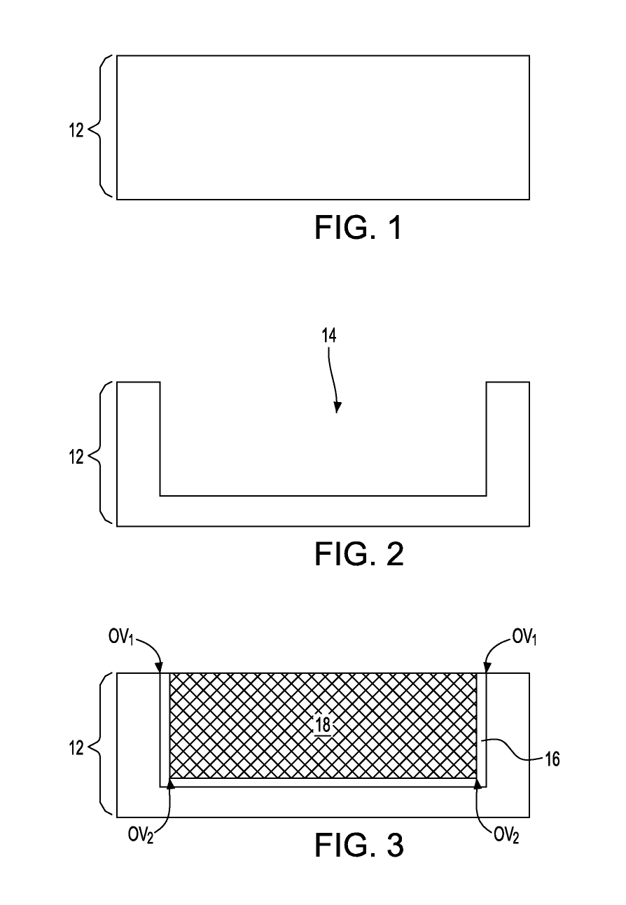

Reference is first made to FIG. 1 which illustrates an initial structure that can be employed in one embodiment of the present disclosure. The initial structure includes a dielectric material 12. The dielectric material 12 is typically located upon a substrate (not shown in the drawings of the present application). The substrate, which is not shown, may comprise a semiconducting material, an insulating material, a conductive material or any combination including multilayers thereof. When the substrate is comprised of a semiconducting material, any semiconductor such as, for example, Si, SiGe, SiGeC, SiC, Ge alloys, GaAs, InAs, InP and other III/V or II/VI compound semiconductors may be used. In addition to these listed types of semiconducting materials, the present disclosure also contemplates cases in which the semiconductor substrate is a layered semiconductor such as, for example, Si/SiGe, Si/SiC, silicon-on-insulators (SOIs) or silicon germanium-on-insulators (SGOIs). In some embodiments of the present disclosure, the semiconducting material may include one or more semiconductor devices such as, for example, complementary metal oxide semiconductor (CMOS) devices fabricated thereon.

When the substrate is an insulating material, the insulating material can be an organic insulator, an inorganic insulator or a combination thereof including multilayers. When the substrate is a conducting material, the substrate may include, for example, polySi, an elemental metal, alloys of elemental metals, a metal silicide, a metal nitride or combinations thereof including multilayers.

When the substrate comprises a combination of an insulating material and a conductive material, the substrate may represent one of interconnect levels of a multilayered interconnect structure.

The dielectric material 12 of the initial structure may include any interlevel or intralevel dielectric material including inorganic dielectrics or organic dielectrics. The dielectric material 12 may be porous, non-porous or contain regions and/or surfaces that are porous and other regions and/or surfaces that may be non-porous. Some examples of suitable dielectrics that can be used as the dielectric material 12 include, but are not limited to, silsesquioxanes, C doped oxides (i.e., organosilicates) that include atoms of Si, C, O and H, thermosetting polyarylene ethers, or multilayers thereof. The term “polyarylene” is used in this application to denote aryl moieties or inertly substituted aryl moieties which are linked together by bonds, fused rings, or inert linking groups such as, for example, oxygen, sulfur, sulfone, sulfoxide, carbonyl and the like.

In one embodiment, the dielectric material 12 has a dielectric constant that is less than silicon dioxide, i.e., less than 4.0. In another embodiment, the dielectric material 12 that can be employed in the present disclosure has a dielectric constant of 3.0 or less. All dielectric constants mentioned herein are relative to a vacuum, unless otherwise noted. Dielectrics which have a dielectric constant of less than that of silicon dioxide generally have a lower parasitic cross talk as compared with dielectric materials that have a higher dielectric constant equal to, or greater than, silicon dioxide. Generally, silicon dioxide has a dielectric constant of 4.0.

The thickness of the dielectric material 12 may vary depending upon the composition of the dielectric material used as well as the exact number of dielectric layers within the dielectric material 12. In one embodiment, the dielectric material 12 has a thickness from 50 nm to 1000 nm. In other embodiments, the dielectric material 12 can have a thickness that is greater than or less than the thickness range mentioned above. The dielectric material 12 can be formed utilizing a deposition process such as, for example, chemical vapor deposition (CVD), plasma enhanced chemical vapor deposition (PECVD), evaporation, chemical solution deposition and spin-on coating.

In some embodiments of the present disclosure and after forming the dielectric material 12, a hard mask material (not shown) can be formed on an exposed upper (i.e., topmost) surface of dielectric material 12. In other embodiments, the hard mask material is not employed.

When employed, the hard mask material may include an oxide, nitride, oxynitride or multilayers thereof (e.g., a stack comprising at least two hard mask materials). In one embodiment, the hard mask material comprises a semiconductor oxide such as, for example, silicon dioxide. In another embodiment, the hard mask comprises a stack of an oxide hard mask material such as, for example, silicon dioxide, and a nitride hard mask material such as, for example, silicon nitride. In some embodiments, the hard mask material may be formed utilizing a deposition process including, for example, CVD, PECVD, evaporation, chemical solution deposition, physical vapor deposition (PVD) and atomic layer deposition (ALD). In other embodiments, the hard mask material can be formed by a thermal process such as, for example, thermal oxidation, and/or thermal nitridation. In yet other embodiments, the hard mask material can be formed utilizing a combination of deposition and thermal processes. The thickness of the hard mask material may vary depending on the composition of the hard mask material itself as well as the technique that was used in forming the same. Typically, the hard mask material has a thickness from 10 nm to 80 nm.

After forming the initial structure shown in FIG. 1, at least one opening 14 as shown, for example in FIG. 2, can be formed into the dielectric material 12. In one embodiment, the hard mask material is employed as a pattern mask. The at least one opening 14 may include a via opening, a line opening, a combined via and line opening, or any combination thereof. A via opening can be distinguished from a line opening in that the via opening has a narrower width than the line opening. In the drawings, a line opening is shown by way of a non-limiting example.

In one embodiment and as shown in FIG. 2, the at least one opening 14 extends partially through the dielectric material 12. In another embodiment (not shown), the at least one opening 14 can extend entirely through the dielectric material 12, i.e., from the upper surface of the dielectric material 12 to the bottom surface of the dielectric material 12. In some embodiments, a first set of openings can extend partially through the dielectric material 12, while a second set of openings can extend entirely through the dielectric material 12.

The at least one opening 14 can formed by lithography and etching. The lithographic step may include forming a photoresist (organic, inorganic or hybrid) atop the dielectric material 12. In one embodiment, the photoresist can be formed directly on the upper surface of the dielectric material 12. In another embodiment, and when the hard mask material is present, the photoresist can be formed directly on the upper surface of the hard mask material. The photoresist can be formed utilizing a deposition process such as, for example, CVD, PECVD and spin-on coating. Following formation of the photoresist, the photoresist is exposed to a desired pattern of radiation. Next, the exposed photoresist is developed utilizing a conventional resist development process.

After the development step, an etching step can be performed to transfer the pattern from the patterned photoresist into at least the dielectric material 12. In one embodiment, and when the hard mask material is present, the pattern may be first transferred into the hard mask material and then into the dielectric material 12. In such an embodiment, the patterned photoresist is typically, but not necessarily always, removed from the surface of the structure after transferring the pattern into the hard mask material utilizing a resist stripping process such as, for example, ashing. The etching step used in forming the at least one opening 14 may include a dry etching process (including, for example, reactive ion etching, ion beam etching, plasma etching or laser ablation), a wet chemical etching process or any combination thereof. In one embodiment, reactive ion etching is used to form the at least one opening 14.

Referring now to FIG. 3, there is illustrated the structure of FIG. 2 after forming a diffusion barrier material 16 and a first conductive material 18 within the opening 14 and thus materials 16 and 18 are each embedded entirely within the dielectric material 12. As illustrated in FIG. 3, the diffusion barrier 16 and the first conductive material 18 each have an upper surface that is coplanar with an upper surface of the dielectric material 12. The diffusion barrier 16 that is within the opening 14 is U-shaped. The term “U-shaped” as used throughout the present disclosure denotes any contiguous material such as diffusion barrier 16 that includes two vertical portions which upward extend from a horizontal connecting portion.

The diffusion barrier 16 can include any material that can serve as a barrier to prevent conductive material ions from diffusing into the dielectric material 12. Examples of materials that can be used as diffusion barrier 16 include, for example, Ta, TaN, Ti, TiN, Ru, RuN, RuTa, RuTaN, IrTa, IrTaN, W, WN or a multilayered stack thereof. The thickness of the diffusion barrier 16 may vary depending on the deposition process used as well as the material employed. Typically, the diffusion barrier 16 has a thickness from 4 nm to 40 nm, with a thickness from 7 nm to 20 nm being more typical. The diffusion barrier 16 can be formed by a deposition process including, for example, CVD, PECVD, PVD, sputtering and plating.

The first conductive material 18, which will be used as the lower electrode of the MIM capacitor of the present disclosure, includes for example, a conductive metal, an alloy comprising at least two conductive metals, a conductive metal oxide, a conductive metal nitride, a conductive metal silicide or any combination thereof. In one embodiment, the first conductive material 18 can comprise Al, Ti, TiN, Ta, TaN, W, WN, MoN, Pt, Pd, Os, Ru, IrO₂, ReO₂, and/or ReO₃. In another embodiment, the first conductive material 18 can comprise Cu and/or a Cu alloy (such as AlCu). The first conductive material 18 can be formed by a deposition process including, for example, CVD, PECVD, PVD, sputtering, plating, chemical solution deposition and electroless plating.

After deposition of each of the diffusion barrier 16 and the first conductive material 18, any excess diffusion barrier material and first conductive material that is located outside of the at least one opening 14 can be removed by a planarization process. In one embodiment, the planarization process includes chemical mechanical polishing (CMP). In another embodiment, the planarization process includes grinding. In a further embodiment, the planarization process includes a combination of CMP and grinding. In some embodiments and when a hard mask material is employed, the planarization process also removes remaining portions of the hard mask material that are located outside the opening 14 and on the upper surface of dielectric material 12. As shown, the diffusion barrier 16 has outermost vertical edges OV₁, while the first conductive material 18 has outermost vertical edges OV₂. Each outermost vertical edge OV₁ of the diffusion barrier 16 is in direct contact with a portion of the dielectric material 12, and each outermost vertical edge OV₂ of the first conductive material 18 is in direct contact with an innermost vertical edge of the diffusion barrier 16.

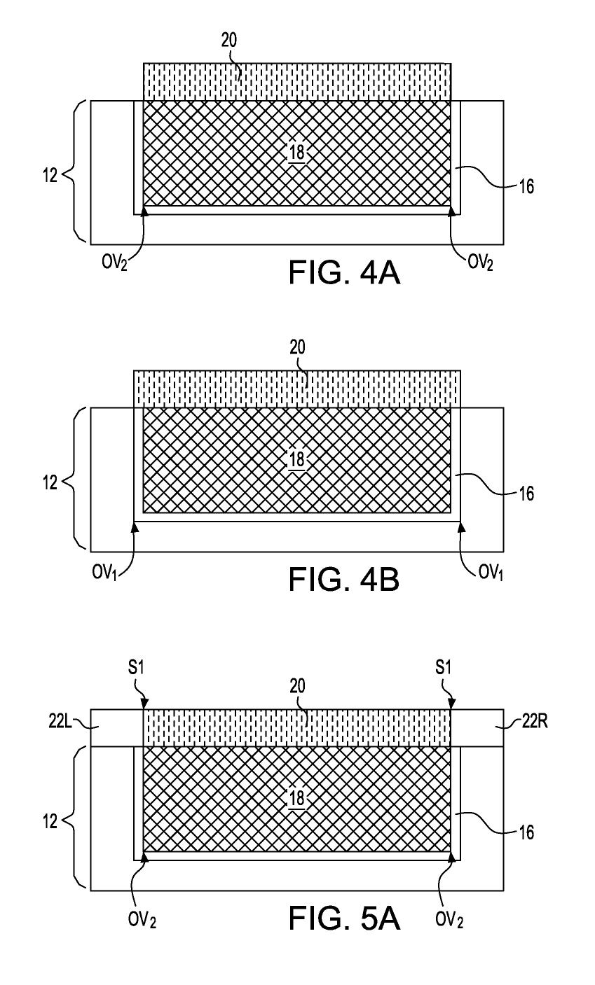

Referring to FIG. 4A, there is illustrated the structure of FIG. 3 after selective deposition of a sacrificial metal material 20 on the upper surface of the first conductive material 18. In FIG. 4A, the sacrificial metal material 20 has vertical edges that are vertically coincident with the outermost vertical edges OV₂ of the first conductive material 18. Stated in other terms, the sacrificial metal material 20 shown in the embodiment depicted by FIG. 4A has vertical edges that do not extend beyond the outermost vertical edges OV₂ of the first conductive material 18.

Referring to FIG. 4B, there is illustrated the structure of FIG. 3 after selective deposition of a sacrificial metal material 20 on the upper surface of both the first conductive material 18 and the diffusion barrier 16. In FIG. 4B, the sacrificial metal material 20 has vertical edges that are vertically coincident with the outermost vertical edges OV₁ of the diffusion barrier material 16. The outermost vertical edges OV₁ of the diffusion barrier 16 are defined as sidewall surfaces of the diffusion barrier that come in direct contact with a portion of dielectric material 12. In contrast, the innermost vertical edges of the diffusion barrier 16 are defined as sidewall surfaces of the diffusion barrier 16 that come in direct contact with the first conductive material 18. Stated in other terms, the sacrificial metal material 20 as shown in the embodiment depicted in FIG. 4B has vertical edges that do not extend beyond the outermost vertical edges OV₁ of the diffusion barrier 16.

In either embodiment, the sacrificial metal material 20 does not extend onto the upper surface of the dielectric material 12 that is adjacent to the now filled opening 14. Also, the sacrificial metal material 20 is used in either embodiment as a mask layer in the process of the present disclosure and aids in forming a MIM capacitor in which the dielectric material of the MIM capacitor is self-aligned to one of the diffusion barrier 16 or the first conductive material 18.

Notwithstanding which particular embodiment is employed, the sacrificial metal material 20 that can be employed in the present disclosure includes any metal or metal alloy which has a different composition than that of the first conductive material 18. In one embodiment, the sacrificial metal material 20 is selected from Ru, Ir, Rh, Pt, Co, Mn and alloys thereof such as CoWP. In some embodiments, the sacrificial metal material 20 can be comprised of a single material. In other embodiments, the sacrificial metal material 20 can be comprised of more than one material which can be stacked one atop the other. The thickness of the sacrificial metal material 20 may vary. In one embodiment, the sacrificial metal material 20 has a thickness from 1 Å to 500 Å. In another embodiment, the sacrificial metal material 20 has a thickness from 10 Å to 200 Å.

The sacrificial metal material 20 used in the various embodiments of the present disclosure can be formed utilizing a low temperature chemical deposition process including, for example, CVD, PECVD, low pressure CVD and ALD. By “low temperature”, it is meant a deposition temperature of 200° C. or less. In one embodiment, the deposition is performed at a temperature from room temperature (i.e., 20° C.-30° C.) to 150° C. Deposition temperatures exceeding 200° C. are not generally utilized in the present disclosure since the same may result in extending the sacrificial metal material 20 onto the upper surface of the dielectric material 12. In some embodiments, the deposition conditions are selected to provide a deposition rate of the sacrificial metal material 20 onto the first conductive material 18 that is from 0.2 Å/sec. to 0.8 Å/sec. Deposition rates which are not within the aforementioned range may result in forming a discontinuous sacrificial metal material 20 atop the first conductive material 18 or forming a sacrificial metal material that may extend onto the exposed upper surface of the dielectric material 12.

The degree of selective deposition of the sacrificial metal material 20 onto either the first conductive material 18 or atop both the diffusion barrier 16 and the first conductive material 18 depends on many factors including the deposition temperature, the flow rate of gases including carrier gases and/or the type of precursor gas employed.

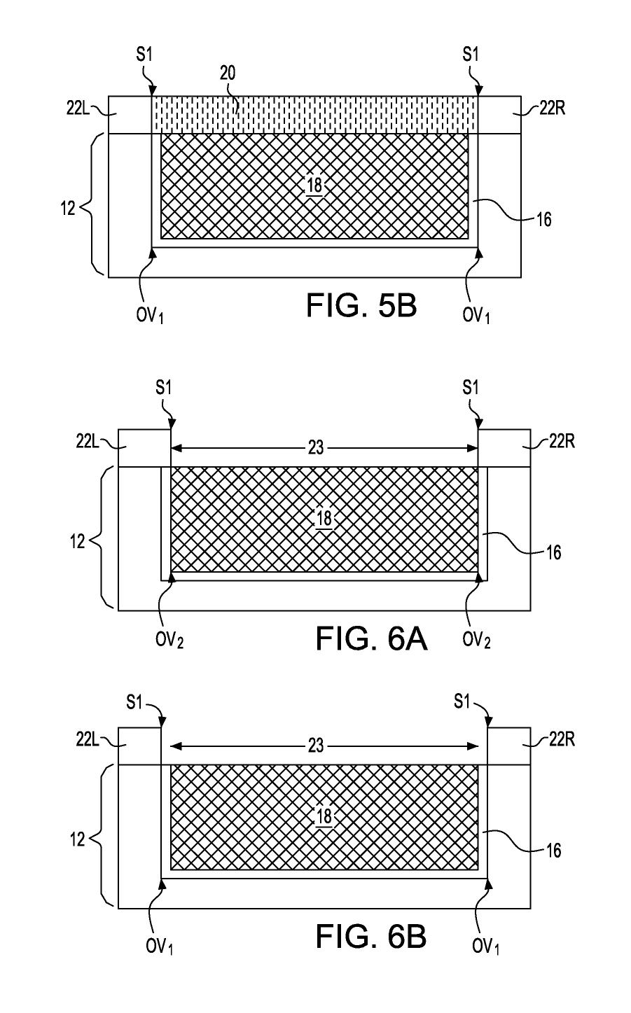

Referring to FIGS. 5A-5B, there are illustrated the structures of FIGS. 4A and 4B, respectively, after deposition of an insulator material and then etching back, i.e., removing, the insulator material. In the drawings, reference numerals 22L, 22R represent insulator material portions that are formed after deposition and etching back the insulator material.

The insulator material that is used in forming the insulator material portions 22L, 22R can be comprised of any material having insulating properties. In one embodiment, the insulator material that is used in forming the insulator material portions 22L, 22R can be porous. In another embodiment, the insulator material that is used in forming the insulator material portions 22L, 22R can be non-porous. Porous dielectric materials typically have a lower dielectric constant than there corresponding non-porous counterparts. The insulator material that is used in forming the insulator material portions 22L, 22R may comprise a same or a different dielectric material as the first dielectric material 12. Some examples of suitable dielectrics that can be used as the insulator material that is used in forming the insulator material portions 22L, 22R include, but are not limited to, silicon dioxide, silsesquioxanes, C doped oxides (i.e., organosilicates) that include atoms of Si, C, O and H, thermosetting polyarylene ethers, or multilayers thereof.

The thickness of the insulator material that is used in forming the insulator material portions 22L, 22R may vary depending upon the type of dielectric material used as well as the exact number of dielectrics layers within the insulator material that is used in forming the insulator material portions 22L, 22R. In one embodiment, the insulator material that is used in forming the insulator material portions 22L, 22R that is formed after deposition, but prior to etching back, is from 1 nm to 200 nm.

The insulator material that is used in forming the insulator material portions 22L, 22R can be formed utilizing one of the deposition processes mentioned above in forming dielectric material 12. Alternatively, a thermal oxidation can be used in forming the insulator material that is used in forming the insulator material portions 22L, 22R.

After depositing the insulator material, the deposited insulator material is etched back utilizing any conventional etch back process that is well known to those skilled in the art. In one embodiment, a chemical mechanical planarization process can be used in etching back the insulator material.

After etching back the deposited insulator material, insulator material portions 22L, 22R are provided that have an upper surface that is coplanar with an upper surface of the sacrificial metal material 20. As shown in FIG. 5A, a bottom surface of each insulator material portion 22L, 22R is located on an upper surface of the dielectric material 12 as well as the upper surface of the diffusion barrier 16. In this embodiment, the sidewall surface S1 of each dielectric insulator material portion 22L, 22R is vertically coincident with the outermost vertical edge OV₂ of the first conductive material 18. As shown in FIG. 5B, a bottom surface of each insulator material portion 22L, 22R is located on an upper surface of only the dielectric material 12. In this embodiment, the sidewall surface S1 of each dielectric insulator material portion 22L, 22R is vertically coincident with the outermost vertical edge OV₁ of the diffusion barrier 16. In either embodiment, each insulator material portion 22L, 22R has a sidewall surface S1, i.e., vertical edge, which is in direct contact with a vertical edge of the sacrificial metal material 20.

Referring now to FIGS. 6A-6B, there are illustrated the structures of FIGS. 5A-5B, respectively, after selectively removing the sacrificial metal material 20. In the embodiment illustrated in FIG. 5A, the upper surface of only the first conductive material 18 is exposed after selectively removing the sacrificial metal material 20. In the embodiment illustrated in FIG. 5B, the upper surfaces of both the first conductive material 18 and the diffusion barrier 16, but not the dielectric material 12, are exposed after selectively removing the sacrificial metal material 20.

The selective removal of the sacrificial metal material 20 does not remove the insulator material portions 22L, 22R from the structure and thus forms a gap 23 between adjacent insulator material portions 22L, 22R. In one embodiment and as shown in FIG. 6A, the width of the gap 23 between insulator material portion 22L and insulator material portion 22R equals the width of the first conductive material 18. In another embodiment and as shown in FIG. 6B, the width of the gap 23 between insulator material portion 22L and insulator material portion 22R equals the width of the first conductive material 18 plus the widths of each upper surface of the diffusion barrier 16.

The selective removal of the sacrificial metal material 20 may comprise a dry etching process including reactive ion etching, plasma etching, and ion beam etching. Alternatively, a chemical wet acid etch may be employed in selectively removing the sacrificial metal material 20 from the structure. In one embodiment, a dry etch utilizing NF₃ and N₂ chemistry can be employed.

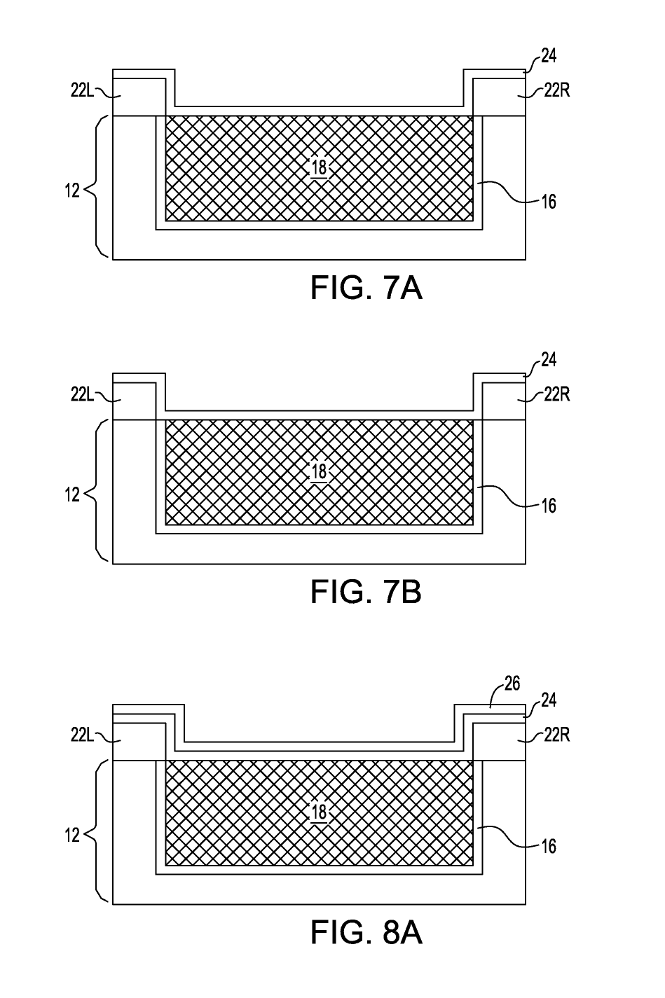

Referring now to FIGS. 7A-7B, there are illustrated the structures of FIGS. 6A-6B, respectively, after deposition of an optional adhesion layer 24. As shown in FIG. 6A, the optional adhesion layer 24 is deposited on the upper surface of the first conductive material 18 within gap 23 as well as sidewall surfaces and atop each insulator material portion 22L, 22R. As shown in FIG. 6B, the optional adhesion layer 24 is deposited on the upper surface of the first conductive material 18 and the upper surface of the diffusion barrier 16 within gap 23 as well as sidewall surfaces and atop each insulator material portion 22L, 22R.

The optional adhesion layer 24 may include one of the materials mentioned above for diffusion barrier 16. In one embodiment, the optional adhesion layer 24 includes Ta(N) or Ti(N). The optional adhesion layer 24 can be formed utilizing one of the techniques mentioned above for diffusion barrier 16 and the thickness of optional adhesion layer 24 is within the range mentioned above for diffusion barrier 16.

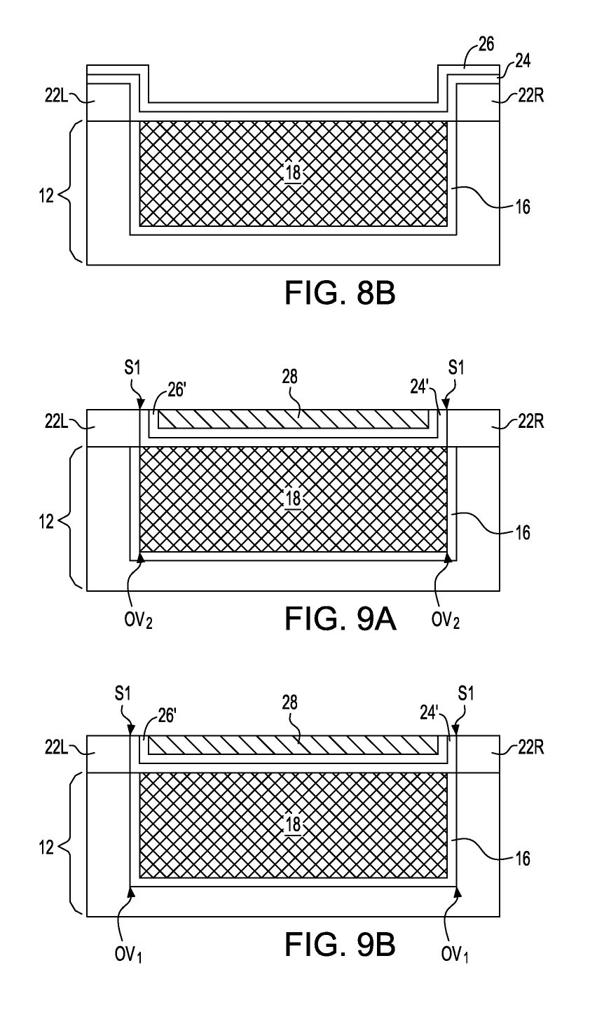

Referring now to FIGS. 8A-8B, there are illustrated the structures of FIGS. 7A-7B, respectively, after deposition of a dielectric material 26 having a dielectric constant of equal to, or greater than, silicon dioxide. In one embodiment and as illustrated in FIGS. 8A-8B, the dielectric material 26 is located on the upper surface of the optional adhesion layer 24. In other embodiments and when no adhesion layer 24 is present, the dielectric material 26 is deposited on the upper surface of the first conductive material 18, optionally the upper surface of the diffusion barrier 16 as well as sidewall surfaces and atop each insulator material portion 22L, 22R.

The dielectric material 26 that is employed in the present disclosure includes any material having insulating properties and a dielectric constant that is equal to, or greater than, silicon dioxide. Dielectric materials having dielectric constants greater than silicon dioxide, which can also be used as dielectric material 26, may be referred to as high k dielectric materials. In one embodiment, the dielectric material 26 that can be employed in the present disclosure is a high k dielectric material having a dielectric constant of 8.0 or greater. In another embodiment, the dielectric material 26 that can be employed in the present disclosure is a high k dielectric material having a dielectric constant of 10.0 or greater.

Exemplary dielectrics that can be employed as dielectric material 26 include, but are not limited to, silicon dioxide, HfO₂, ZrO₂, La₂O₃, Al₂O₃, TiO₂, SrTiO₃, LaAlO₃, Y₂O₃, HfOₓN_{y}, ZrOₓN_{y}, La₂OₓN_{y}, Al₂OₓN_{y}, TiOₓN_{y}, SrTiOₓN_{y}, LaAlOₓN_{y}, Y₂OₓN_{y}, SiON, SiNₓ, PSiNₓ, a silicate thereof, and an alloy thereof. Multilayered stacks of these dielectric materials can also be employed as the dielectric material 26. For example, a stack containing silicon dioxide and HfO₂ can be employed as dielectric material 26. Each value of x is independently from 0.5 to 3 and each value of y is independently from 0 to 2.

The thickness of dielectric material 26 that can be employed may vary depending on the technique used to form the same. Typically, the dielectric material 26 that can be employed has a thickness from 1 nm to 20 nm, with a thickness from 2 nm to 10 nm being more typical.

The dielectric material 26 can be formed by methods well known in the art. In one embodiment, the dielectric material 26 can be formed by a deposition process such as, for example, chemical vapor deposition (CVD), plasma enhanced chemical vapor deposition (PECVD), physical vapor deposition (PVD), molecular beam deposition (MBD), pulsed laser deposition (PLD), liquid source misted chemical deposition (LSMCD), and atomic layer deposition (ALD). If the dielectric material 26 is a stack of several layers, some of the layers can be deposited by chemical solution deposition or spin-on technique.

Referring now to FIGS. 9A-9B, there are illustrated the structures of FIGS. 8A-8B, respectively, after deposition of a second conductive material 28 and etching back, i.e., removing, excess second conductive material such that the entirely of the second conductive material 28 after deposition and etch back is located within gap 23. The etch back step also removes portions of the optional adhesion layer 24 and the dielectric material 26 that are outside gap 23 and positioned atop the upper horizontal surface of each insulator material portion 22L, 22R. In FIGS. 9A-9B, element 24′ denotes a remaining portion of the optional adhesion layer 24 (hereinafter referred to as “optional adhesion liner 24′) and element 26′ denotes a remaining portion of the dielectric material (hereinafter referred to as “dielectric material liner 26′). After performing the etch back process, the optional adhesion liner 24′ and dielectric material liner 26′ are each U-shaped. It is noted that the dielectric material liner 26′ serves as the insulator component of the MIM capacitor of the present disclosure, while the second conductive material 28 serves as the upper electrode of the MIM capacitor of the present disclosure.

Prior to performing the etching back step, and as stated above, second conductive material 28 is formed. In one embodiment, second conductive material 28 may comprise a same conductive material as first conductive material 18. In another embodiment, second conductive material 28 may comprise a different conductive material as first conductive material 18.

In one embodiment, the second conductive material 28 may comprise a single conductive material. In another embodiment, the second conductive material 28 may comprise two dissimilar conductive materials. In yet another embodiment, the second conductive material may comprise three dissimilar materials. The second conductive material 28 can be formed utilizing one of the deposition processes mentioned above in forming the first conductive material 18. The deposition process typically, but not necessarily always, overfills the gap 23 that is positioned between adjacent dielectric material portions 22L, 22R.

Thus, after deposition of the second conductive material 28, and as mentioned above, an etch back process can be employed to remove at least the excess second conductive material 28 that is formed outside the gap 23 that is positioned between two adjacent dielectric material portions 22L, 22R. Etching back, i.e., removing the excess second conductive material 28 from the structure, can be performed utilizing any conventional etch back process that is well known to those skilled in the art. In one embodiment, a chemical mechanical planarization process can be used in etching back the second conductive material 28.

FIGS. 9A and 9B depict a semiconductor structure, i.e., MIM capacitor structure, of the present disclosure. The structure includes a diffusion barrier 16 and a first conductive material 18 embedded within a dielectric material 12. The diffusion barrier 16 separates the first conductive material 18 from the dielectric material 12. The diffusion barrier 16 and the first conductive material 18 have upper surfaces that are coplanar with an upper surface of the dielectric material 12. The structure further includes insulator material portions 22L, 22R that are present at least on the upper surface of the dielectric material 12, each insulator material portion having a sidewall surface S1 that is vertically coincident to an outermost vertical edge OV₁ of the diffusion barrier 16 or an outermost vertical edge OV₂ of the first conductive material 18. In FIG. 9A, each sidewall surface S1 of the insulator material portion 22L, 22R is vertically coincident to the outermost vertical edge OV₂ of the first conductive material 18, while in FIG. 9B, each sidewall surface S1 of the insulator material portion 22L, 22R is vertically coincident to the outermost vertical edge OV₁ of the diffusion barrier 14. The structure of the present disclosure further includes a dielectric material liner 26′ having a dielectric constant of equal to, or greater than, silicon dioxide located atop the first conductive material 18 and located between the insulator material portions 22L, 22R. The dielectric material liner 26′ has vertical portions that extend from a horizontal connecting portion. The structure further includes a second conductive material 28 positioned between the vertical portions of the dielectric material liner 26′ and located atop the horizontal connecting portion of the dielectric material liner 26′. The dielectric material liner 26′ and the second conductive material 28 have upper surfaces that are coplanar with each other and with an upper surface of each insulator material portion 22L, 22R.

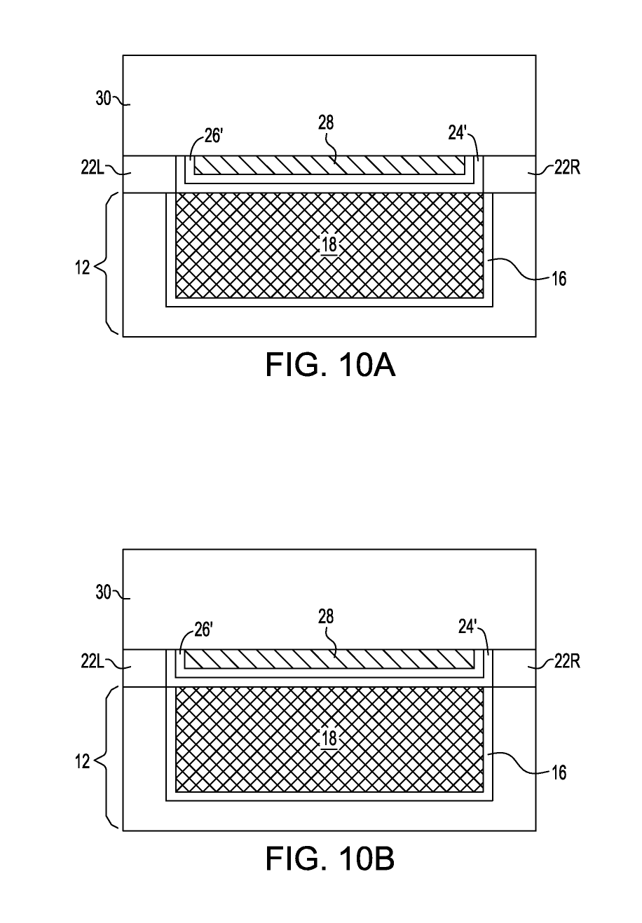

Referring now to FIGS. 10A-10B, there are illustrated the structures of FIGS. 9A-9B, respectively, after deposition of another dielectric material 30. In one embodiment, the another dielectric material 30 may comprise one of the dielectric materials used for in forming the first dielectric material 12. The another dielectric material 30 can be formed utilizing one of the deposition techniques mentioned above in forming the first dielectric material 12 and the thickness of the another dielectric material 30 can be within the thickness range mentioned above for dielectric material 12.

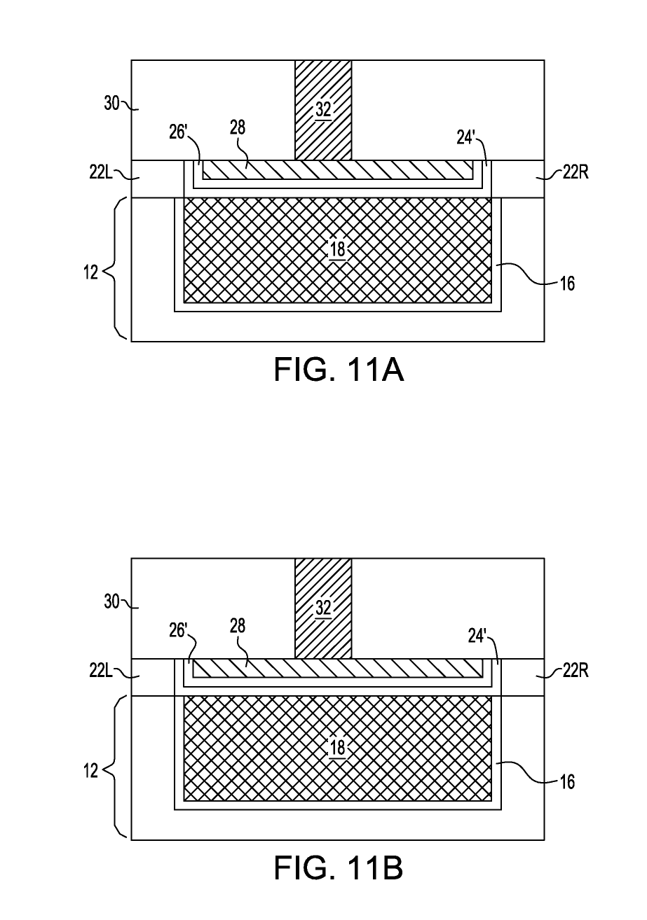

Referring now to FIGS. 11A-11B, there are illustrated the structures of FIGS. 10A-10B, respectively, after formation of a contact opening within the another dielectric material 30 and filling the contact opening with a third conductive material 32. An optional planarization process may follow the filling of the contact opening with the third conductive material 32. The contact opening can be formed utilizing lithography and etching as is described above, for example, for forming opening 14 within dielectric material 12. The contact opening can be a via contact opening, a line contact opening or a combined via and line contact opening.

The third conductive material 32 can include one of the materials mentioned above for the first conductive material 18. In one embodiment, the third conductive material 32 may comprise a same material as the first and second conductive materials 18 and 28, respectively. In another embodiment, the third conductive material 32 may comprise a different material as the first and second conductive materials 18 and 28, respectively. In yet another embodiment, the third conductive material 32 may comprise a same material as the first conductive material 18, but a different material as the second conductive material 28. In yet a further embodiment, the third conductive material 32 may comprise a different material as the first conductive material 18, but a same conductive material as the second conductive material 28. In some embodiments, a diffusion barrier can be formed within the contact opening prior to forming the third conductive material 32.

While the present disclosure has been particularly shown and described with respect to various embodiments thereof, it will be understood by those skilled in the art that the foregoing and other changes in forms and details may be made without departing from the spirit and scope of the present disclosure. It is therefore intended that the present disclosure not be limited to the exact forms and details described and illustrated, but fall within the scope of the appended claims.

What is claimed is:

1. A semiconductor structure comprising:
a diffusion barrier and a first conductive material embedded within a dielectric material, wherein the diffusion barrier separates the first conductive material from the dielectric material and wherein the diffusion barrier and the first conductive material have upper surfaces that are coplanar with an upper surface of the dielectric material;
insulator material portions present at least on the upper surface of the dielectric material, each insulator material portion having a sidewall surface that is vertically coincident to an outermost vertical edge of the diffusion barrier or an outermost vertical edge of the first conductive material;
a dielectric material liner having a dielectric constant of equal to, or greater than, silicon dioxide located atop the first conductive material and between said insulator material portions, wherein said dielectric material liner has vertical portions that extend from a horizontal connecting portion; and
a second conductive material positioned between the vertical portions of said dielectric material liner and located atop the horizontal connecting portion of said dielectric material liner, wherein said dielectric material liner and said second conductive material have upper surfaces that are coplanar with each other and with an upper surface of each insulator material portion.

2. The semiconductor structure of claim 1, wherein said sidewall surface of each insulator material portion is vertically coincident with the outermost edge of the diffusion barrier, and wherein said dielectric material portions are present only on the upper surface of the dielectric material.

3. The semiconductor structure of claim 1, wherein said sidewall surface of each insulator material portion is vertically coincident with the outermost edge of the first conductive material, and wherein said dielectric material portions extend onto the upper surface of said diffusion barrier.

4. The semiconductor structure of claim 1, further comprising an adhesion liner present beneath the dielectric material liner and located atop the first conductive material, said adhesion liner having vertical portions that extend from a horizontal connecting portion, said vertical portions of the adhesion liner are in contact with said sidewall surfaces of said insulator material portions.

5. The semiconductor structure of claim 1, wherein said first and second conductive materials are comprised of a same or different conductive material selected from Cu, Cu alloys Ta, TaN, Ti, TiN, Ru, RuN, RuTa, RuTaN, IrTa, IrTaN, W, and WN.

6. The semiconductor structure of claim 1, further comprising another dielectric material located atop said insulator material portions, said dielectric material liner and said second conductive material, wherein said another dielectric material includes a third conductive material embedded therein, and wherein a bottom surface of the third conductive material contacts said upper surface of the second conductive material.

7. The semiconductor structure of claim 1, wherein said dielectric material liner comprises a dielectric material having a dielectric constant of 8.0 or greater.

8. The semiconductor structure of claim 1, wherein said second conductive material is comprised of a single conductive material.

9. The semiconductor structure of claim 1, wherein said second conductive material is comprised of two conductive materials.

10. The semiconductor structure of claim 1, wherein said second conductive material is comprised of three conductive materials.

11. The semiconductor structure of claim 1, wherein said vertical portions of said dielectric material liner are in direct contact with said sidewall surfaces of said insulator material portions.

12. A method of forming a semiconductor structure comprising:
forming a diffusion barrier and a first conductive material embedded within a dielectric material, wherein the diffusion barrier separates the first conductive material from the dielectric material and wherein the diffusion barrier and the first conductive material have upper surfaces that are coplanar with an upper surface of the dielectric material;
providing insulator material portions on at least the upper surface of said dielectric material, wherein a sidewall surface of each insulator material portion is vertically coincident to an outermost vertical edge of said diffusion barrier or an outermost vertical edge of said first conductive material; and
forming a dielectric material liner having a dielectric constant of equal to, or greater than, silicon dioxide and a second conductive material between said insulator material portions, wherein said dielectric material liner is positioned between the first and second conductive materials, and wherein said dielectric material liner and said second conductive material have upper surfaces that are coplanar with each other and with an upper surface of each insulator material portion.

13. The method of claim 12, wherein said providing the insulator material portions comprises:
depositing a sacrificial metal material on at least the upper surface of the first conductive material;
depositing an insulator material;
etching back said insulator material; and
removing said sacrificial metal material exposing at least the upper surface of the first conductive material.

14. The method of claim 13, wherein a portion of said sacrificial metal material extends onto the upper surface of the diffusion barrier, and wherein after removing said sacrificial metal material said upper surface of the diffusion barrier and the first conductive material are exposed.

15. The method of claim 12, further comprising forming an adhesion liner between said insulator material portions prior to forming said dielectric material liner.

16. The method of claim 12, wherein said forming the dielectric material liner and the second conductive material comprises:
depositing a dielectric material having said dielectric constant;
depositing said second conductive material; and
removing portions of said dielectric material having said dielectric constant and said second conductive material that are located atop each insulator material portion.

17. The method of claim 12, wherein said sidewall surface of each insulator material portion is vertically coincident with the outermost edge of the diffusion barrier, and wherein said dielectric material portions are present only on the upper surface of the dielectric material.

18. The method of claim 12, wherein said sidewall surface of each insulator material portion is vertically coincident with the outermost edge of the first conductive material, and wherein said dielectric material portions extend onto the upper surface of the diffusion barrier.

19. The method of claim 13, wherein said depositing the sacrificial metal material is performed utilizing a deposition temperature of about 200° C. or less.

20. The method of claim 13, further comprising forming another dielectric material located atop said insulator material portions, said dielectric material liner and said second conductive material, wherein said another dielectric material includes a third conductive material embedded therein, and wherein a bottom surface of the third conductive material contacts said upper surface of the second conductive material.
